(19) United States
(12) Patent Application Publication
(10) Pub. No.: US 2025/0052826 A1
(43) Pub. Date: Feb. 13, 2025

(54) POWER BATTERY MONITORING SYSTEM AND METHOD

(71) Applicant: Autel Intelligent Technology Corp., Ltd., Shenzhen (CN)

(72) Inventor: Weilin WANG, Shenzhen (CN)

(73) Assignee: Autel Intelligent Technology Corp., Ltd., Shenzhen, GD (CN)

(21) Appl. No.: 18/928,821

(22) Filed: Oct. 28, 2024

Related U.S. Application Data
(63) Continuation of application No. PCT/CN2023/081670, filed on Mar. 15, 2023.

(30) Foreign Application Priority Data
Apr. 27, 2022 (CN) 202210458752.7

(51) Int. Cl. G01R 31/3835; G01R 19/165; G01R 31/367; G01R 31/396

(52) U.S. Cl. CPC G01R 31/3835; G01R 19/16542; G01R 31/367; G01R 31/396

(57) ABSTRACT

The present disclosure provides a power battery monitoring system and a method. The system includes a battery assembly, N monitoring assemblies and an upper monitoring platform. The N monitoring assemblies are connected in series with each other, and a first monitoring assembly is connected with the upper monitoring platform, wherein the number of sampling channels of each monitoring assembly is M. The power battery monitoring system can segment the battery cells; the number of the battery cells in each segment is M; the battery cells in each segment are connected with a same monitoring assembly; and the N monitoring assemblies acquire sampling data of the battery cells in this segment through the corresponding sampling channel, so as to realize the monitoring of the battery cells in this segment by the upper monitoring platform.

### CROSS-REFERENCE TO RELATED APPLICATIONS

This application is a continuation application of International Patent Application No. PCT/CN2023/081670 filed on Mar. 15, 2023, which claims priority to Chinese Patent Application No. 202210458752.7, filed on Apr. 27, 2022, the entire disclosures of which are incorporated herein by reference for all purposes.

### TECHNICAL FIELD

The present disclosure relates to the field of power batteries, in particular to a power battery monitoring system and a method.

### BACKGROUND

The power battery of a new energy vehicle is formed by a plurality of battery assemblies connected in series or connected in parallel and then connected in series. Each battery assembly is formed by a plurality of battery cells connected in series (or connected in parallel and then connected in series). When the power battery is charged and discharged, the voltage of each battery cell and the temperature of the battery assemblies must be monitored to ensure that the voltage of each battery cell and the temperature of the battery assemblies are within a normal working range to prevent overcharge, overdischarge or overtemperature, which may cause damage to the battery.

Generally, sampling lines are led from both ends of the battery cell and a temperature sensor to monitor the voltage of the battery cell and the temperature of the battery assemblies. The battery assemblies from different manufacturers or vehicle models have very different configurations, and are generally composed of at least 3 strings of battery cells and at most dozens or hundreds of strings of battery cells. The existing power battery monitoring system cannot be compatible with different types of battery assemblies and has poor compatibility.

### SUMMARY

Embodiments of the present disclosure solve at least one of the above technical problems to a certain extent. Thus, the present disclosure provides a power battery monitoring system and method, which can monitor various types of battery assemblies and have better compatibility.

In a first aspect, embodiments of the present disclosure provide a power battery monitoring system. The power battery monitoring system includes a battery assembly, N monitoring assemblies and an upper monitoring platform:
where the battery assembly includes a plurality of battery cells connected in series or in parallel;
the N monitoring assemblies are connected in series with each other, and a first monitoring assembly is connected with the upper monitoring platform, where a number of sampling channels of each monitoring assembly is M; M battery cells are connected with a same monitoring assembly through the M sampling channels; a sequence of the M sampling channels is consistent with a sequence of the M battery cells; M and N are integers greater than or equal to 1; and the N monitoring assemblies are used for acquiring the sampling data of the M battery cells; and
the upper monitoring platform is used for monitoring battery assemblies according to the sampling data.

In a second aspect, embodiments of the present disclosure provide a power battery monitoring method applied to the above power battery monitoring system. The power battery monitoring method includes:
acquiring, by the upper monitoring platform, parameter information of the monitoring assemblies;
establishing, by the upper monitoring platform, a mapping relationship of the parameter information, communication addresses and weights of the monitoring assemblies through a bootstrap algorithm;
acquiring, by the monitoring assemblies, the sampling data of the battery cells, and determining serial numbers of the corresponding battery cells in the monitoring assemblies according to the sampling data; and
when the battery cell is abnormal, determining, by the upper monitoring platform, a location of the abnormal battery cell according to the serial number of the corresponding battery cell in the monitoring assembly and the mapping relationship, and monitoring the battery cell.

In a third aspect, embodiments of the present disclosure provide a power battery monitoring device, including one or more processors; and a memory in communication connection with the one or more processors, wherein the memory stores instructions that can be executed by the one or more processors, and the instructions are executed by the one or more processors to enable the one or more processors to perform any of the above-mentioned power battery monitoring methods.

In a fourth aspect, embodiments of the present disclosure provide a non-transitory computer-readable storage medium, wherein the non-transitory computer-readable storage medium stores computer-executable instructions which are used to enable a computer to perform the above-mentioned power battery monitoring method.

### BRIEF DESCRIPTION OF DRAWINGS

One or more embodiments are exemplarily illustrated with reference to drawings in the corresponding accompanying drawings. These exemplary illustrations do not constitute a limitation on the embodiments, elements having the same reference numerals in the accompanying drawings represent similar elements, and the drawings in the accompanying drawings do not constitute a limitation on scales, unless otherwise specified.

FIG. 1 is a structural schematic diagram of a power battery monitoring system according to an embodiment of the present disclosure;

FIG. 2 is a structural schematic diagram of a monitoring assembly and an upper monitoring platform according to an embodiment of the present disclosure;

FIG. 3 is a flow chart of a power battery monitoring method according to an embodiment of the present disclosure;

FIG. 4 is a flow chart of step S32 in FIG. 3;

FIG. 5 is a flow chart of step S33 in FIG. 3;

FIG. 6 is a flow chart of step S34 in FIG. 3;

FIG. 7 is a structural schematic diagram of a power battery monitoring device according to an embodiment of the present disclosure;

FIG. 8 is a structural schematic diagram of a first controller according to an embodiment of the present disclosure; and

FIG. 9 is a structural schematic diagram of a second controller according to an embodiment of the present disclosure.

### DETAILED DESCRIPTION OF THE INVENTION

To make the purpose, the technical solution and the advantages of the present disclosure clear, the present disclosure will be further described below in detail in combination with the drawings and the embodiment. It should be understood that specific embodiments described herein are only used for explaining the present disclosure, not used for limiting the present disclosure. Based on the embodiments in the present disclosure, all other embodiments obtained by those ordinary skilled in the art without contributing creative labor will belong to the protection scope of the present disclosure.

It should be noted that if there is no conflict, the features in the embodiments of the present disclosure can be mutually combined, and are within the protection scope of the present disclosure. In addition, although the functional modules are divided in the device diagram and the logical sequence is shown in the flow chart, in some cases, the steps shown or described can be performed in a different module division in the device or different sequence in the flow chart. Furthermore, the words “first,” “second,” and “third” used in the present disclosure do not limit the data and the sequence of execution, but only distinguish the same or similar items with basically the same function and effect.

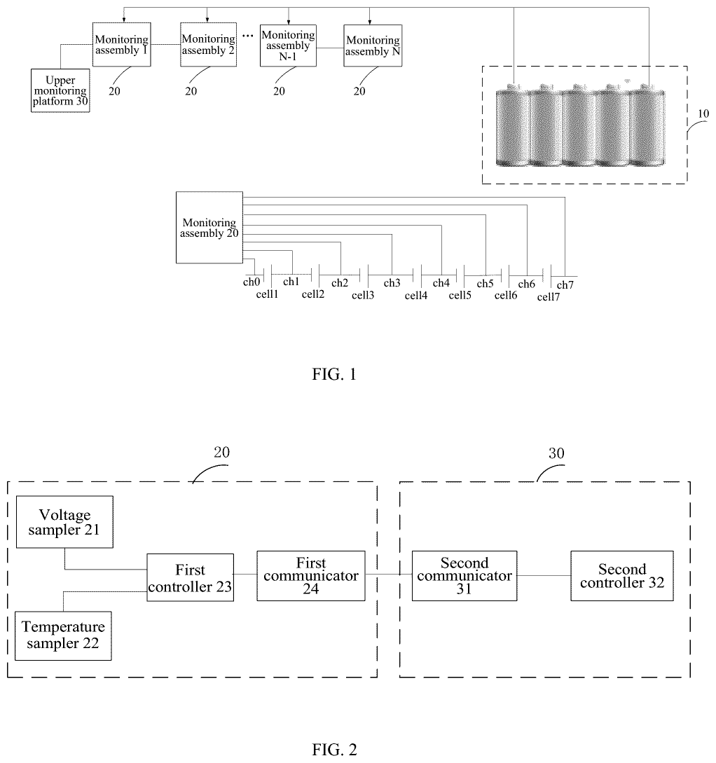

FIG. 1 is a structural schematic diagram of a power battery monitoring system according to an embodiment of the present disclosure. As shown in FIG. 1, the power battery monitoring system includes a battery assembly 10, N monitoring assemblies 20 and an upper monitoring platform 30. The battery assembly 10 includes a plurality of battery cells connected in series and/or in parallel. Different battery assemblies 10 include different number of battery cells. The plurality of battery cells may be connected in parallel to increase the capacity of the battery cells, and may be then connected in series to form a battery assembly 10 to increase the total voltage value of the battery assembly 10.

Different battery assemblies 10 include different number of battery cells, and thus need different number of sampling channels and monitoring assemblies 20. One sampling cable is shared between two adjacent battery cells. M+1 sampling cables are needed for M battery cells. As shown in FIG. 1, 7 battery cells, i.e., cell 1 to cell 7, require 8 sampling cables. If the voltage of the battery cells needs to be sampled, 7 sampling channels are required.

N monitoring assemblies 20 are connected in series, and the first monitoring assembly 20 is connected to the upper monitoring platform 30, and electrically connected to the upper monitoring platform 30, so that the upper monitoring platform 30 can supply power to the monitoring assembly 20, and can also supply power to the monitoring assembly 20 through an external power supply. The first monitoring assembly 20 is also in communication connection with the upper monitoring platform 30 to transmit the sampling data of the battery cells to the upper monitoring platform 30, so that the upper monitoring platform 30 monitors the battery assembly 10 according to the sampling data. Wherein the sampling data includes voltage, or voltage and temperature. In some other embodiments, the sampling data may also include parameters such as current.

The number of the sampling channels of each monitoring assembly 20 is M, and M battery cells are connected with the same monitoring assembly 20 through M sampling channels. The sequence of the M sampling channels is consistent with the sequence of the M battery cells. The monitoring assembly 20 is used for acquiring the sampling data of the battery cells through the sampling channels.

For example, as shown in FIG. 1, M is 7, so 7 sampling channels are connected with the same monitoring assembly 20, and the sequence of the 7 sampling channels is consistent with the sequence of the 7 battery cells, from cell 1 to cell 7.

The M sampling channels can be used to obtain the sampling data, or some sampling channels can be deprecated. For example, if M is 24, i.e., the number of the sampling channels of the monitoring assembly 20 is 24, but the number of the battery cells is 7, then only 7 sampling channels are used in the monitoring assembly 20 to acquire the sampling data of the battery cells and other sampling channels are deprecated. Moreover, the sequence of the sampling channels is consistent with the sequence of the battery cells.

The first monitoring assembly 20 is a monitoring assembly 1, and the last monitoring assembly 20 is a monitoring assembly N. The monitoring assembly 1 to the monitoring assembly N are connected in series, and the monitoring assembly 1 is connected with the upper monitoring platform 30.

When there are a large number of battery cells, the battery cells can be segmented. The number of the battery cells in each segment can be consistent with the number of the sampling channels of one monitoring assembly 20. However, the battery cells in each segment are not necessarily connected according to the sequence of the monitoring assemblies 2. For example, the battery cells in the first segment are connected with the monitoring assembly 2, the battery cells in the second segment are connected with the monitoring assembly 4, the battery cells in the third segment are connected with the monitoring assembly 1, and the battery cells in the fourth segment are connected with the monitoring assembly 3. The upper monitoring platform 30 can automatically identify the sequence of each monitoring assembly 20 and the sequence of the corresponding battery cell connected with the monitoring assembly 20 through a bootstrap algorithm, which is more convenient for users.

The upper monitoring platform 30 acquires the sampling data sent by the monitoring assemblies 20 and monitors the battery assemblies 10 according to the sampling data. For example, it is determined whether the battery cell is abnormal according to the sampling data; when the battery cell is abnormal, the location of the abnormal battery cell is determined. Abnormal conditions may include, but are not limited to, overvoltage, overcharge, overcurrent, and temperature anomalies.

The upper monitoring platform 30 can be achieved by an individual upper computer or achieved by a charge-and-discharge machine which is used to charge and discharge the battery assemblies 10 and monitor the battery assemblies 10 at the same time. The monitoring assemblies 20 are used for acquiring the sampling data of the battery cells, which is equivalent to separating the sampling part of the battery assemblies 10 from the inside of the charge-and-discharge machine, so that the users can select different types of monitoring assemblies 20 and the number of the monitoring assemblies 20 according to the configuration of different battery assemblies 10, and the monitoring assemblies 20 can be compatible with different types of battery assemblies 10, which also makes the charge-and-discharge machine more miniaturized in design.

The types of the sampling channels may include voltage sampling channels, current sampling channels, temperature sampling channels and multiplexing sampling channels. In some embodiments, the M sampling channels are voltage sampling channels, and then the sampling data is voltage. In some embodiments, the M-P sampling channels are the voltage sampling channels, the P sampling channels are the temperature sampling channels, and then the sampling data are voltage and temperature. In some embodiments, the M-R sampling channels are the voltage sampling channels, and the R sampling channels are the multiplexing sampling channels. The multiplexing sampling channels can be used for transmitting voltage data, and can also be used for transmitting temperature data. The monitoring assemblies 20 can configure the specific purpose of the multiplexing sampling channels as needed, and then the sampling data is voltage or voltage and temperature, wherein P and R are integers greater than or equal to 1. For example, if M is 24, a monitoring assembly 20 can support 24 voltage sampling channels, or simultaneously support 20 voltage sampling channels and 4 temperature sampling channels, or 16 voltage sampling channels and 8 multiplexing sampling channels.

To sum up, the power battery monitoring system can segment the battery cells; the number of the battery cells in each segment is M; the battery cells in each segment are connected with the same monitoring assembly 20; and the monitoring assemblies 20 acquire the sampling data of the battery cells in this segment through the corresponding sampling channel, so as to realize the monitoring of the battery cells in this segment by the upper monitoring platform 30. In addition, each monitoring assembly 20 can also be connected in series to achieve the expansion of the monitoring assemblies 20. Therefore, the power battery monitoring system can select the number of the monitoring assemblies 20 according to the specific number of the battery cells, is compatible with the battery assemblies 10 with various configurations, and has better compatibility.

FIG. 2 is a structural schematic diagram of a monitoring assembly according to an embodiment of the present disclosure. As shown in FIG. 2, the monitoring assembly 20 includes a voltage sampler 21, a temperature sampler 22 and a first controller 23.

One end of the voltage sampler 21 is connected with the battery cell through the sampling channel, and the other end thereof is connected with the first controller 23 for sampling the voltage of the battery cell. One end of the temperature sampler 22 is connected with the battery cells through the sampling channels, and the other end thereof is connected with the first controller 23 for sampling the temperature of the battery cells. The first controller 23 is also connected with the upper monitoring platform 30, and the first controller 23 is used for acquiring the voltage, or the voltage and the temperature.

Wherein the voltage sampler 21 and the temperature sampler 22 can be any device capable of realizing the corresponding sampling function. In some embodiments, the temperature sampler 22 may adopt a PTC resistor or an NTC resistor, and the voltage sampler 21 may adopt a voltage sampling sensor.

In some embodiments, the first controller 23 can be a general purpose processor, a digital signal processor (DSP), an application-specific integrated circuit (ASIC), a field programmable gate array (FPGA), a single-chip microcomputer, an ARM (Acorn RISC Machine) or other programmable logic devices, a discrete gate or transistor logic, a discrete hardware component, or any combination of these components. Furthermore, the first controller 23 can be any traditional processor, controller, microcontroller or state machine. The first controller 23 may also be implemented as a combination of computing devices, for example, a combination of DSP and microprocessor, multiple microprocessors, one or more microprocessors combined with DSP and/or any other such configuration. The first controller 23 can also be an inverter board or a main control board of a washing machine.

In some embodiments, the monitoring assemblies 20 further include a first communicator 24, the first communicator 24 is in communication connection with the first controller 23 and the upper monitoring platform 30 respectively, and a communication type is CAN communication or CAN FD communication. In other embodiments, the communication type may also be other communication modes other than CAN.

When a plurality of monitoring assemblies 20 are connected in series, the first controller 23 can be in communication connection with the first monitoring assembly 20 through the first communicator 24, and the first monitoring assembly 20 can be in communication connection with the communicators of other monitoring assemblies 20 through the first communicator 24. In other embodiments, the first controller 23 is in direct communication connection with the communicators of all monitoring assemblies 20 to receive the sampling data of the battery assemblies 10 transmitted by the corresponding monitoring assemblies 20.

In some embodiments, as also shown in FIG. 2, the upper monitoring platform 30 includes a second controller 32 and a second communicator 31; the second communicator 31 is in communication connection with the monitoring assemblies 20 and the second controller 32 respectively, and specifically connected with the first communicator 24 to acquire the sampling data; and the second controller 32 is used for monitoring the battery assemblies 10 according to the sampling data.

The second controller 32 can determine whether the battery cell in the battery assembly 10 has abnormal conditions such as overcharge, overvoltage or overtemperature according to the sampling data. When the abnormal condition is determined, a corresponding control command is issued to protect the battery assembly 10.

The upper monitoring platform 30 can also automatically identify the sequence of the connected monitoring assembly 20, and register the segmenting sequence of the battery cell connected with the monitoring assembly 20 through the bootstrap algorithm by the connection information of the sampling channels, so as to ensure that the registered sequence of the monitoring assemblies 20 is consistent with the sequence of the battery cells in the battery assemblies 10. For example: the monitoring assembly 1 is connected with the battery cell in the second segment, the monitoring assembly 2 is connected with the battery cell in the first segment, and the monitoring assembly 3 is connected with the battery cell in the third segment. Then, the upper monitoring platform 30 can identify the sequence of the corresponding battery cells connected with the monitoring assemblies 20 through the bootstrap algorithm, and the registered sequence of the assemblies is “the monitoring assembly 2, the monitoring assembly 1 and the monitoring assembly 3”, to ensure that the registration sequence is consistent with the segmentation sequence of the battery cells. Therefore, no matter whether the user accesses the upper monitoring platform 30 according to the sequence of the monitoring assemblies 20, the upper monitoring platform 30 can automatically identify the sequence of the monitoring assemblies 20, which is more convenient for the users to operate.

In some embodiments, the second controller 32 can be a general-purpose processor, a digital signal processor (DSP), an application-specific integrated circuit (ASIC), a field programmable gate array (FPGA), a single-chip microcomputer, an ARM (Acorn RISC Machine) or other programmable logic devices, a discrete gate or transistor logic, a discrete hardware component, or any combination of these components. Furthermore, the second controller 32 can be any traditional processor, controller, microcontroller or state machine. The second controller 32 may also be implemented as a combination of computing devices, for example, a combination of DSP and microprocessor, multiple microprocessors, one or more microprocessors combined with DSP and/or any other such configuration. The second controller 32 can also be an inverter board or a main control board of a washing machine.

The battery cells are connected with the monitoring assemblies 20 through cable plugs. One end of the cable plugs is connected with the battery cells. The sampling channels in the cable plugs are in the same sequence as that of the battery cells. For example: as shown in FIG. 1, the number of the battery cells in a certain segment is 7, and the sequence of the battery cells is cell 1 to cell 7. Then, the sampling channels in the cable plugs are in the same sequence as that of the battery cells, and 8 sampling cables are required. The first sampling channel corresponds to ch0 sampling point and ch1 sampling point, and the second sampling channel corresponds to ch1 sampling point and ch2 sampling point, and so on. The seventh sampling channel corresponds to ch6 sampling point and ch7 sampling point. The other end of the cable plugs is connected with the monitoring assemblies 20. The cable plugs can be inserted into the monitoring assemblies 20 in a positive sequence or in a reverse sequence. The monitoring assemblies 20 can automatically detect the positive and negative insertion sequence, which is convenient for the users to operate.

After the cable plug is connected to the monitoring assembly 20, the monitoring assembly 20 can also automatically detect the type of the sampling channel. When the sampling channel is a voltage sampling channel, it is specially used to sample the voltage of the battery cell. After the voltage sampling channel is determined, a P line (with lowest voltage) and a Q line (with highest voltage) in the channel can be determined.

To sum up, the power battery monitoring system can segment the battery cells; the number of the battery cells in each segment is M; the battery cells in each segment are connected with the same monitoring assembly 20; and the monitoring assemblies 20 acquire the sampling data of the battery cells in this segment through the corresponding sampling channel, so as to realize the monitoring of the battery cells in this segment by the upper monitoring platform 30. In addition, each monitoring assembly 20 can also be connected in series to achieve the expansion of the monitoring assemblies 20. Therefore, the power battery monitoring system can select the number of the monitoring assemblies 20 according to the specific number of the battery cells, is compatible with the battery assemblies 10 with various configurations, and has better compatibility.

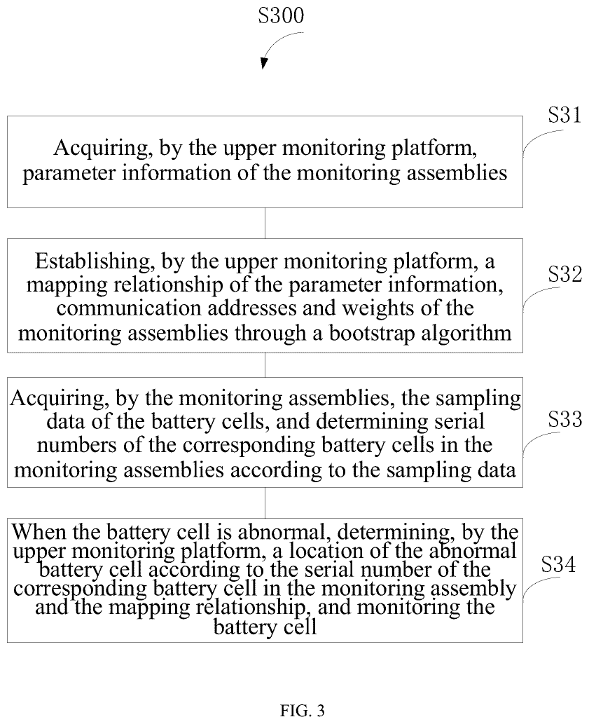

FIG. 3 is a flow chart of a power battery monitoring method according to an embodiment of the present disclosure and applied to the above power battery monitoring system. As shown in FIG. 3, the method S300 includes:

S31, acquiring, by the upper monitoring platform, parameter information of the monitoring assemblies.

The parameter information of the monitoring assemblies includes the types and the number of the sampling channels of the monitoring assemblies. The parameter information of the monitoring assemblies can be stored in the monitoring assemblies in advance, and can be acquired directly by the upper monitoring platform. The parameter information of the monitoring assemblies can also be counted in real time, and transmitted to the upper monitoring platform after the type and corresponding number of the sampling channels are determined. If there are N monitoring assemblies, the upper monitoring platform acquires the parameter information of each monitoring assembly respectively, and registers and records the parameter information accordingly.

In some embodiments, before the upper monitoring platform acquires the parameter information of the monitoring assemblies, the type of the sampling channels can be detected in advance and the corresponding number can be counted. Specifically, the monitoring assemblies acquire the first voltage through the sampling channels. When the first voltage is greater than a first preset threshold or the first voltage is less than a second preset threshold, the sampling channel is determined as the voltage sampling channel, and the number of the voltage sampling channels is counted. The remaining sampling channels are determined as the temperature sampling channels, and the number of the temperature sampling channels is counted.

When the first voltage is greater than the first preset threshold, the sampling channels are voltage sampling channels and in all voltage sampling channels, the first voltage sampling channel is the P line (with the lowest voltage), and the last voltage sampling channel is the Q line (with the highest voltage).

When the first voltage is less than a second preset threshold, the sampling channels are voltage sampling channels, and in all voltage sampling channels, the last voltage sampling channel is the P line (with the lowest voltage), and the first voltage sampling channel is the Q line (with the highest voltage).

Wherein the first preset threshold and the second preset threshold can be set as needed. In the embodiment of the present disclosure, the first preset threshold is 1.0 V, and the second preset threshold is −1.0 V.

In other embodiments, the parameter information of the monitoring assemblies also includes the number of multiplexing sampling channels. The monitoring assemblies can store the number of the voltage sampling channels, the number of the temperature sampling channels and the number of the multiplexing sampling channels in advance, and transmit the number of the sampling channels to the upper monitoring platform for the upper monitoring platform to record.

S32, establishing, by the upper monitoring platform, a mapping relationship of the parameter information, communication addresses and weights of the monitoring assemblies through a bootstrap algorithm.

If the number of the monitoring assemblies is N and the N monitoring assemblies are connected in series, each monitoring assembly corresponds to a segment of the battery cells, but the segment sequences of the monitoring assemblies and the battery cells are not necessarily in one-to-one correspondence. Therefore, the sequence of the monitoring assemblies can be identified through the bootstrap algorithm to make it consistent with the segment sequence of the battery cells, and assign the corresponding communication address to the monitoring assemblies based on the sequence.

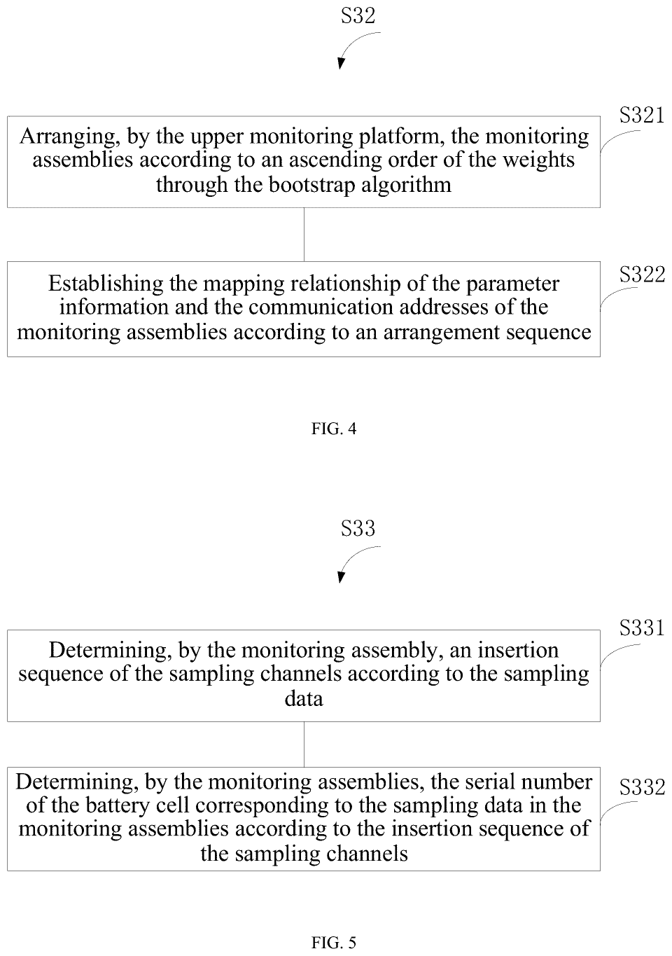

As shown in FIG. 4, step S32 includes:

S321, arranging, by the upper monitoring platform, the monitoring assemblies according to an ascending order of the weights through the bootstrap algorithm.

The battery cells are divided into multiple segments in order, and each segment is connected with the same monitoring assembly. The higher the segment sequence, the smaller the weight w and the higher the sequence of the monitoring assembly. The communication addresses are assigned for the monitoring assemblies according to the sequence of the arranged monitoring assemblies. For example: the monitoring assembly 1 is connected with the battery cells of the third segment, and the third segment has 7 battery cells; the monitoring assembly 2 is connected with the battery cells of the first segment, and the first segment has 6 battery cells; the monitoring assembly 3 is connected with the battery cells of the second segment, and the second segment has 6 battery cells. Then the upper monitoring platform acquires the weight w of each monitoring assembly through the bootstrap algorithm, and arranges the monitoring assemblies in ascending order of the weight w. Therefore, the sequence of the monitoring assemblies is “the monitoring assembly 2, the monitoring assembly 3, and the monitoring assembly 1”. The communication addresses are assigned for the monitoring assemblies according to this sequence. The communication address of the monitoring assembly 2 is id100 and serial number is 1; the communication address of the monitoring assembly 3 is id101 and serial number is 2; and the communication address of the monitoring assembly 1 is id102 and serial number is 3.

S322, establishing the mapping relationship of the parameter information and the communication addresses of the monitoring assemblies according to an arrangement sequence.

The mapping relationship of the parameter information and the assigned communication addresses of the monitoring assemblies is established according to an ascending order, which can be specifically realized through a table. After the table is completed, the mapping relationship is stored in the upper monitoring platform for subsequent operation.

Specifically, if there are three monitoring assemblies in the above embodiment, the mapping table is shown in Table 1:

TABLE 1
Mapping Table

| | | | | Number of | Number of |
|---|---|---|---|---|---|
| | | | | voltage | temperature |
| Serial | Monitoring | | | sampling | sampling |
| number | assembly | CAN id | Weight w | channels | channels |
| 1 | Monitoring | id100 | w1 | 24 | 0 |
| | assembly 2 | | | | |
| 2 | Monitoring | id101 | w2 | 24 | 0 |
| | assembly 3 | | | | |
| 3 | Monitoring | id102 | w3 | 10 | 2 |
| | assembly 1 | | | | |

The monitoring assembly 2 corresponds to the first segment of battery cells, with serial number of 1 and the communication address of id100. The number of the voltage sampling channels is 24. The monitoring assembly 3 corresponds to the second segment of battery cells, with serial number of 2 and the communication address of id101. The number of the voltage sampling channels is 24. The monitoring assembly 1 corresponds to the third segment of battery cells, with serial number of 3 and the communication address of id102. The number of the voltage sampling channels is 10 and the number of the temperature sampling channels is 2.

S33, acquiring, by the monitoring assemblies, the sampling data of the battery cells, and determining serial numbers of the corresponding battery cells in the monitoring assemblies according to the sampling data.

The monitoring assemblies and the battery cells are connected through the cable plugs. One end of the cable plugs is connected with a certain segment of battery cells in the battery assembly. The sequence of the sampling channels in the cable plugs is consistent with the sequence of the battery cells in this segment. The other end of the cable plugs is inserted into the monitoring assemblies by a positive sequence or reverse sequence. The sequence in which the cable plugs are inserted into the monitoring assemblies can be determined by the sampling voltage acquired from the sampling channel or channel resistance between the sampling channels.

As shown in FIG. 5, step S33 includes:

S331, determining, by the monitoring assembly, an insertion sequence of the sampling channels according to the sampling data.

The insertion sequence of the sampling channels is the sequence in which the cable plugs are inserted into the monitoring assemblies in the above embodiments, which includes a positive insertion sequence and a reverse insertion sequence, and the specific insertion sequence of the sampling channels can be determined by the sampling data.

In an embodiment, a detection method of the insertion sequence is:
(1) acquiring the first sampling voltage of the first sampling channel; when the first sampling voltage is greater than a third preset threshold, determining the insertion sequence of the sampling channels as the positive insertion sequence; when the first sampling voltage is less than a fourth preset threshold, determining the insertion sequence of the sampling channels as the reverse insertion sequence; otherwise, going to (2);
(2) acquiring the second sampling voltage of the last sampling channel; when the second sampling voltage is less than the fourth preset threshold, determining the positive insertion sequence; when the second sampling voltage is greater than the third preset threshold, determining the reverse insertion sequence; otherwise, going to (3);
(3) detecting the first 8 sampling channels in the sampling channels, acquiring the channel resistance between the sampling channels, and acquiring the channel resistance in a set {(1,2),(3,4),(5,6),(7,8)}; when there is a channel resistance greater than a fifth preset threshold and less than a sixth preset threshold, determining the reverse insertion sequence; otherwise, going to (4);
(4) if there are M sampling channels, acquiring the channel resistance in a set {(M−7,M−6),(M−5,M−4),(M−3,M−2),(M−1,M)}; when there is a channel resistance greater than the fifth preset threshold and less than the sixth preset threshold, determining the positive insertion sequence; otherwise, going to (5);
(5) making the cable plugs not connected with the battery assemblies or not inserted into the monitoring assemblies.

Wherein the third preset threshold, the fourth preset threshold, the fifth preset threshold and the sixth preset threshold can be set as required. In the embodiment of the present disclosure, the third preset threshold, the fourth preset threshold, the fifth preset threshold and the sixth preset threshold are 1V, −1V, 100Ω, and 10 MΩ respectively.

S332, determining, by the monitoring assemblies, the serial number of the battery cell corresponding to the sampling data in the monitoring assemblies according to the insertion sequence of the sampling channels.

when the sampling channels are inserted in the positive sequence, the serial numbers of the sampling channels are consistent with the serial numbers of the corresponding battery cells in the monitoring assemblies; when the sampling channels are inserted in the reverse sequence, the serial numbers of the sampling channels are also in reverse order with the serial numbers of the corresponding battery cells in the monitoring assemblies.

For example, if the monitoring assembly has eight sampling channels and the cable plugs are inserted in a positive sequence, the battery cell corresponding to the first sampling channel is the first battery cell, and the serial number in the monitoring assembly is 1. If the cable plugs are inserted in a reverse sequence, the battery cell corresponding to the first sampling channel is the last battery cell in the corresponding battery cell segment of the monitoring assembly, that is, the serial number of the eighth battery cell in the segment of the bacterial cells is 8 in the monitoring assembly.

S34, when the battery cell is abnormal, determining, by the upper monitoring platform, a location of the abnormal battery cell according to the serial number of the corresponding sampling channel and the mapping relationship, and monitoring the battery cell.

According to the acquired sampling data, it is determined whether the corresponding battery cell is abnormal. When the battery cell is abnormal, the specific location of the abnormal battery cell is determined to facilitate processing of the abnormal battery cell. The specific location of the battery cell is determined according to the serial number of the corresponding sampling channel in the monitoring assembly and the number of the sampling channels in each monitoring assembly.

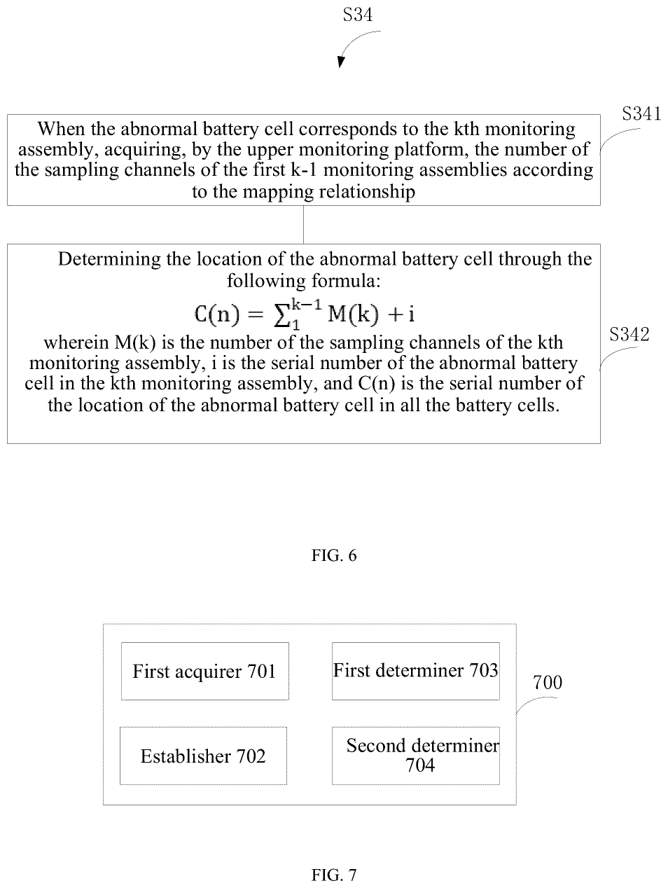

As shown in FIG. 6, step S34 includes: S341, when the abnormal battery cell corresponds to the kth monitoring assembly, acquiring, by the upper monitoring platform, the number of the sampling channels of the first k−1 monitoring assemblies according to the mapping relationship;

S342, determining the location of the abnormal battery cell through the following formula:

$$C ( n ) = {\sum }_{1}^{k - 1} M ( k ) + i$$

where M(k) is the number of the sampling channels of the kth monitoring assembly, i is the serial number of the abnormal battery cell in the kth monitoring assembly, and C(n) is the serial number of the location of the abnormal battery cell in all the battery cells.

That is, the location number of the abnormal battery cell in all battery cells can be n, and the serial number C(n) of the location of the nth battery cell in all battery cells can be determined according to the number of the sampling channels of the first k−1 monitoring assemblies and the sequence of the abnormal unit in the kth monitoring assembly because the abnormal battery cell corresponds to the kth monitoring assembly.

To sum up, the power battery monitoring method can segment the battery cells; the number of the battery cells in each segment is M; the battery cells in each segment are connected with the same monitoring assembly; and the monitoring assemblies acquire the sampling data of the battery cells in this segment through the corresponding sampling channel, so as to realize the monitoring of the battery cells in this segment by the upper monitoring platform. In addition, each monitoring assembly can also be connected in series to achieve the expansion of the monitoring assemblies. Therefore, the power battery monitoring system can select the number of the monitoring assemblies according to the specific number of the battery cells, is compatible with the battery assemblies with various configurations, and has better compatibility.

It should be noted that in each of the above embodiments, there is not necessarily a certain sequence among the above steps. Those ordinary skilled in the art can understand according to the description of the embodiments of the present disclosure that in different embodiments, the above steps can have different execution sequences, that is, they can be executed in parallel, or alternatively, and so on.

As another aspect of the present disclosure, an embodiment of the present disclosure provides a power battery monitoring device. Wherein the power battery monitoring device can be a software module; the software module includes a plurality of instructions which are stored in a memory of electrical modulation; and a processor can access the memory, and call the instructions for execution, to complete the power battery monitoring method illustrated in the above embodiments.

In some embodiments, the power battery monitoring device may also be built by hardware devices. For example, the power battery monitoring device may be built by one or more chips, and the chips may work in coordination with each other to perform the power battery monitoring method illustrated in the above embodiments. For example, the power battery monitoring device can also be built by various logic devices, such as a general-purpose processor, a digital signal processor (DSP), an application-specific integrated circuit (ASIC), a field programmable gate array (FPGA), a single-chip microcomputer, an ARM (Acorn RISC Machine) or other programmable logic devices, a discrete gate or transistor logic, a discrete hardware component, or any combination of these components.

FIG. 7 shows a power battery monitoring device according to an embodiment of the present disclosure. As shown in FIG. 7, the power battery monitoring device 700 includes a first acquirer 701, an establisher 702, a first determiner 703 and a second determiner 704.

The first acquirer 701 is used for the upper monitoring platform to acquire the parameter information of the monitoring assemblies.

The establisher 702 is used for the upper monitoring platform to establish the mapping relationship of the parameter information, the communication address and the weight of the monitoring assemblies through the bootstrap algorithm.

The first determiner 703 is used for the monitoring assemblies to acquire the sampling data of the battery cells and determine the serial number of the corresponding battery cell in the monitoring assembly according to the sampling data.

The second determiner 704 is used for determining, by the upper monitoring platform, a location of the abnormal battery cell according to the serial number of the corresponding battery cell in the monitoring assembly and the mapping relationship when the battery cell is abnormal, and monitoring the battery cell.

Therefore, the power battery monitoring device can segment the battery cells; the number of the battery cells in each segment is M; the battery cells in each segment are connected with the same monitoring assembly; and the monitoring assemblies acquire the sampling data of the battery cells in this segment through the corresponding sampling channel, so as to realize the monitoring of the battery cells in this segment by the upper monitoring platform. In addition, each monitoring assembly may also be connected in series to achieve the expansion of the monitoring assemblies. Therefore, the power battery monitoring system can select the number of the monitoring assemblies according to the specific number of the battery cells, is compatible with the battery assemblies with various configurations, and has better compatibility.

It should be noted that since the power battery monitoring device and the power battery monitoring method in the above embodiments are based on the same inventive idea, the corresponding contents in the above method embodiments are also applicable to the device embodiments and are not detailed here.

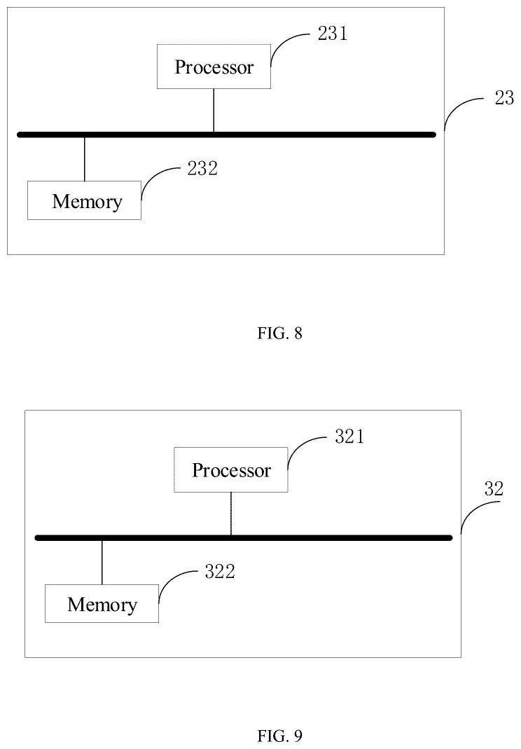

FIG. 8 is a structural schematic diagram of a first controller according to an embodiment of the present disclosure. As shown in FIG. 8, the first controller 23 includes one or more processors 231 and a memory 232, wherein one processor 231 is taken as an example in FIG. 8.

The processor 231 and the memory 232 may be connected by a bus or other means, wherein connection by the bus is taken as an example in FIG. 8.

The memory 232, as a non-volatile computer-readable storage medium, may be used to store non-volatile software programs, non-volatile computer-executable programs and modules, such as program instructions/modules corresponding to the power battery monitoring method in the embodiments of the present disclosure. The processor 231 performs various functional applications and data processing of the power battery monitoring device by running the non-volatile software programs, instructions and modules stored in the memory 232, thereby realizing the functions of the power battery monitoring method provided by the above method embodiments and the functions of each module or unit of the above device embodiments.

The memory 232 may include a high-speed random access memory and may also include a non-volatile memory, such as at least one disk storage device, flash memory device, or other non-volatile solid-state storage devices. In some embodiments, the memory 232 optionally includes memories remotely arranged relative to the processor 231, and these remote memories may be connected to the processor 231 through a network. Examples of the network include, but are not limited to, the Internet, corporate Intranet, local area networks, mobile communication networks and their combinations.

The program instructions/modules are stored in the memory 232 and, when executed by the one or more processors 231, perform the power battery monitoring method in any of the method embodiments.

FIG. 9 is a structural schematic diagram of a second controller according to an embodiment of the present disclosure. As shown in FIG. 9, the structure of the second controller 32 is similar to the structure of the first controller 23 in FIG. 8 and will not be repeated here, wherein the processor and the memory in the second controller 32 may also be the same as the processor and the memory in the first controller 23.

An embodiment of the present disclosure further provides a power battery monitoring device, including one or more processors; and a memory which is in communication connection with the one or more processors, wherein the memory stores instructions that can be executed by the one or more processors, and the instructions are executed by the one or more processors to enable the one or more processors to perform any of the power battery monitoring methods.

An embodiment of the present disclosure further provides a non-transitory computer-readable storage medium that stores computer-executable instructions, and the computer-executable instructions are used to enable a computer to perform the power battery monitoring method.

An embodiment of the present disclosure further provides a computer program product, including a computer program stored on a non-volatile computer-readable storage medium; and the computer program includes program instructions which, when executed by a controller, enable the controller to perform any of the power battery monitoring methods.

Through the above description of the embodiments, those ordinary skilled in the art can clearly understand that the embodiments can be realized by means of software and common hardware platforms, and of course, by hardware. Those ordinary skilled in the art may understand that all or part of the processes in the methods of the embodiments may be completed by instructing the relevant hardware by means of a computer program in a computer program product. The computer program may be stored in a non-transient computer-readable storage medium, and the computer program includes program instructions. When the program instructions are executed by an unmanned aerial vehicle (UAV), the UAV can perform the processes of the embodiments of the methods. Wherein the storage medium may be a magnetic disk, a compact disc, a read-only memory (ROM) or a random access memory (RAM).

Compared with the related art, the present disclosure has at least the following beneficial effects: The power battery monitoring system in the present disclosure includes the battery assembly, the N monitoring assemblies and the upper monitoring platform. The N monitoring assemblies are connected in series with each other, and the first monitoring assembly is connected with the upper monitoring platform, wherein the number of the sampling channels of each monitoring assembly is M; M battery cells are connected with the same monitoring assembly through the M sampling channels; and the sequence of the M sampling channels is consistent with the sequence of the M battery cells. Therefore, the monitoring assemblies can obtain the sampling data of the M battery cells through the M sampling channels and send the sampling data to the upper monitoring platform. The upper monitoring platform monitors the battery assemblies according to the sampling data.

The power battery monitoring system can segment the battery cells; the number of the battery cells in each segment is M; the battery cells in each segment are connected with the same monitoring assembly; and the monitoring assemblies obtain the sampling data of the battery cells in this segment through the corresponding sampling channel, so as to realize the monitoring of the battery cells in this segment by the upper monitoring platform. In addition, each monitoring assembly may also be connected in series to achieve the expansion of the monitoring assemblies. Therefore, the power battery monitoring system can select the number of the monitoring assemblies according to the specific number of the battery cells, is compatible with the battery assemblies with various configurations, and has better compatibility.

Finally, it should be noted that the above embodiments are used only to illustrate the technical solution of the present disclosure, and not to limit it. Under the idea of the present disclosure, the above embodiments or the technical features in different embodiments can be combined, the steps can be implemented in any order, and there are many other changes in various aspects of the present disclosure as described above, which are not provided in detail for the sake of brevity. Although the present disclosure is described in detail by reference to the above embodiments, it should be understood by those ordinary skilled in the art that they may modify the technical solution recorded in the above embodiments or make equivalent replacements for some of the technical features. These modifications or replacements shall not make the corresponding technical solution depart from the scope of the technical solution of each embodiment of the present disclosure.

The above only describes the specific embodiments of the present disclosure, but the protection scope of the present disclosure is not limited to this. Any changes or replacements that can be easily contemplated by those skilled in the art within the technical scope disclosed in the present disclosure shall be covered within the protection scope of the present disclosure. Therefore, the protection scope of the present disclosure shall depend on the scope of the claims.

What is claimed is:

1. A power battery monitoring system, comprising a battery assembly, N monitoring assemblies and an upper monitoring platform; wherein
the battery assembly comprises a plurality of battery cells connected in series or in parallel;
the N monitoring assemblies are connected in series with each other, and a first monitoring assembly of the N monitoring assemblies is connected with the upper monitoring platform, wherein a number of sampling channels of each monitoring assembly is M; M battery cells are connected with a same monitoring assembly through the M sampling channels; a sequence of the M sampling channels is consistent with a sequence of the M battery cells; M and N are integers greater than or equal to 1; and the N monitoring assemblies are configured to acquire sampling data of the M battery cells; and
the upper monitoring platform is configured to monitor battery assemblies according to the sampling data.

2. The power battery monitoring system according to claim 1, wherein the sampling data comprises voltage, or the voltage and temperature, and the N monitoring assemblies comprise a voltage sampler, a temperature sampler and a first controller;
one end of the voltage sampler is connected with the battery cell through the sampling channel, and the other end of the voltage sampler is connected with the first controller for sampling the voltage of the battery cell;
one end of the temperature sampler is connected with the M battery cells through the sampling channels, and the other end of the temperature sampler is connected with the first controller for sampling the temperature of the M battery cells; and
the first controller is connected with the upper monitoring platform, and the first controller is configured to acquire the voltage, or the voltage and the temperature.

3. The power battery monitoring system according to claim 2, wherein the M sampling channels are voltage sampling channels; or, M-P sampling channels are the voltage sampling channels, and P sampling channels are temperature sampling channels; or, M-R sampling channels are the voltage sampling channels, and R sampling channels are multiplexing sampling channels, wherein P and R are integers.

4. The power battery monitoring system according to claim 2, wherein the temperature sampler adopts a Positive Temperature Coefficient (PTC) resistor or a (Negative Temperature Coefficient) NTC resistor.

5. The power battery monitoring system according to claim 1, wherein the N monitoring assemblies further comprise a first communicator, the first communicator is in communication connection with the first controller and the upper monitoring platform respectively with a communication type being Controller Area Network (CAN) communication or CAN (Flexible Data-Rate (FD) communication.

6. The power battery monitoring system according to claim 1, wherein the upper monitoring platform comprises a second controller and a second communicator; wherein
the second communicator is in communication connection with the N monitoring assemblies and the second controller respectively to acquire the sampling data;
the second controller is configured to monitor the battery assemblies according to the sampling data.

7. The power battery monitoring system according to claim 1, wherein the M battery cells and the N monitoring assemblies are connected by cable plugs.

8. The power battery monitoring system according to claim 2, wherein the N monitoring assemblies further comprise a first communicator, the first communicator is in communication connection with the first controller and the upper monitoring platform respectively with a communication type being Controller Area Network (CAN) communication or CAN Flexible Data-Rate (FD) communication.

9. The power battery monitoring system according to claim 3, wherein the N monitoring assemblies further comprise a first communicator, the first communicator is in communication connection with the first controller and the upper monitoring platform respectively with a communication type being CAN communication or CAN FD communication.

10. The power battery monitoring system according to claim 2, wherein the upper monitoring platform comprises a second controller and a second communicator; wherein
the second communicator is in communication connection with the N monitoring assemblies and the second controller respectively to acquire the sampling data;
the second controller is configured to monitor the battery assemblies according to the sampling data.

11. The power battery monitoring system according to claim 2, wherein the M battery cells and the N monitoring assemblies are connected by cable plugs.

12. A power battery monitoring method, applied to a power battery monitoring system, the power battery monitoring system comprising a battery assembly, N monitoring assemblies and an upper monitoring platform; wherein the power battery monitoring method comprises:
acquiring, by the upper monitoring platform, parameter information of monitoring assemblies; wherein the battery assembly comprises a plurality of battery cells connected in series or in parallel; the N monitoring assemblies are connected in series with each other, and a first monitoring assembly of the N monitoring assemblies is connected with the upper monitoring platform, wherein a number of sampling channels of each monitoring module is M; M battery cells are connected with a same monitoring assembly through the M sampling channels; a sequence of the M sampling channels is consistent with a sequence of the M battery cells; M and N are integers greater than or equal to 1; and the N monitoring assemblies are configured to acquire sampling data of the M battery cells;
establishing, by the upper monitoring platform, a mapping relationship of the parameter information, communication addresses and weights of the N monitoring assemblies through a bootstrap algorithm; and
acquiring, by the N monitoring assemblies, the sampling data of the M battery cells, and determining serial numbers of corresponding battery cells in the N monitoring assemblies according to the sampling data; and when a battery cell is abnormal, determining, by the upper monitoring platform, a location of the abnormal battery cell according to a serial number of a corresponding battery cell in the monitoring assembly and the mapping relationship, and monitoring the battery cell.

13. The power battery monitoring method according to claim 12, wherein the parameter information of the N monitoring assemblies comprises the number of the voltage sampling channels and the number of the temperature sampling channels; and before the upper monitoring platform acquires the parameter information of the N monitoring assemblies, the method further comprises:
acquiring, by the N monitoring assemblies, a first voltage through the sampling channel; when the first voltage is greater than a first preset threshold or the first voltage is less than a second preset threshold, determining that the sampling channel is the voltage sampling channel and counting the number of the voltage sampling channels; determining the remaining sampling channels as the temperature sampling channel and counting the number of the temperature sampling channels.

14. The power battery monitoring method according to claim 12, wherein the establishing, by the upper monitoring platform, the mapping relationship of the parameter information, communication addresses and weights of the N monitoring assemblies through a bootstrap algorithm comprises:
arranging, by the upper monitoring platform, the N monitoring assemblies according to an ascending order of the weights through the bootstrap algorithm; and
establishing, by the upper monitoring platform, the mapping relationship of the parameter information and the communication addresses of the N monitoring assemblies according to an arrangement sequence.

15. The power battery monitoring method according to claim 12, wherein the acquiring, by the N monitoring assemblies, the sampling data of the M battery cells, and determining serial numbers of the corresponding battery cells in the N monitoring assemblies according to the sampling data comprises:
determining, by the N monitoring assembly, an insertion sequence of the sampling channels according to the sampling data; and
determining, by the N monitoring assemblies, the serial number of the battery cell corresponding to the sampling data in the N monitoring assemblies according to the insertion sequence of the sampling channels.

16. The power battery monitoring method according to claim 12, wherein the determining, by the upper monitoring platform, the location of the abnormal battery cell according to the serial number of the corresponding battery cell in the monitoring assembly and the mapping relationship comprises:
when the abnormal battery cell corresponds to a kth monitoring assembly, acquiring, by the upper monitoring platform, the number of the sampling channels of first k−1 monitoring assemblies according to the mapping relationship; and
determining, by the upper monitoring platform, the location of the abnormal battery cell through the following formula:
$$C ( n ) = {\sum }_{1}^{k - 1} M ( k ) + i$$
wherein M(k) is the number of the sampling channels of the kth monitoring assembly, i is the serial number of the abnormal battery cell in the kth monitoring assembly, C(n) is the serial number of the location of the abnormal battery cell in all the M battery cells, and k, n are integers.

17. The power battery monitoring method according to claim 13, wherein the determining, by the upper monitoring platform, the location of the abnormal battery cell according to the serial number of the corresponding battery cell in the monitoring assembly and the mapping relationship comprises:
when the abnormal battery cell corresponds to a kth monitoring assembly, acquiring, by the upper monitoring platform, the number of the sampling channels of first k−1 monitoring assemblies according to the mapping relationship; and
determining the location of the abnormal battery cell through the following formula:
$$C ( n ) = {\sum }_{1}^{k - 1} M ( k ) + i$$
wherein M(k) is the number of the sampling channels of the kth monitoring assembly, i is the serial number of the abnormal battery cell in the kth monitoring assembly, C(n) is the serial number of the location of the abnormal battery cell in all the M battery cells, and k, n are integers.

18. The power battery monitoring method according to claim 14, wherein the determining, by the upper monitoring platform, the location of the abnormal battery cell according to the serial number of the corresponding battery cell in the monitoring assembly and the mapping relationship comprises:
when the abnormal battery cell corresponds to a kth monitoring assembly, acquiring, by the upper monitoring platform, the number of the sampling channels of first k−1 monitoring assemblies according to the mapping relationship; and
determining the location of the abnormal battery cell through the following formula:
$$C ( n ) = {\sum }_{1}^{k - 1} M ( k ) + i$$
wherein M(k) is the number of the sampling channels of the kth monitoring assembly, i is the serial number of the abnormal battery cell in the kth monitoring assembly, and C(n) is the serial number of the location of the abnormal battery cell in all the M battery cells, and k, n are integers.

19. The power battery monitoring method according to claim 15, wherein the determining, by the upper monitoring platform, the location of the abnormal battery cell according to the serial number of the corresponding battery cell in the monitoring assembly and the mapping relationship comprises:
when the abnormal battery cell corresponds to a kth monitoring assembly, acquiring, by the upper monitoring platform, the number of the sampling channels of first k−1 monitoring assemblies according to the mapping relationship; and
determining the location of the abnormal battery cell through the following formula:
$$C ( n ) = {\sum }_{1}^{k - 1} M ( k ) + i$$
wherein M(k) is the number of the sampling channels of the kth monitoring assembly, i is the serial number of the abnormal battery cell in the kth monitoring assembly, C(n) is the serial number of the location of the abnormal battery cell in all the M battery cells, and k, n are integers.

20. A power battery monitoring device, comprising
one or more processors; and
a memory in communication connection with the one or more processors, wherein
the memory stores instructions that are configured to be executed by the one or more processors, and the instructions, when executed by the one or more processors, cause the one or more processors to perform acts comprising:
acquiring parameter information of monitoring assemblies; wherein the battery assembly comprises a plurality of battery cells connected in series or in parallel; N monitoring assemblies are connected in series with each other, and a first monitoring assembly of the monitoring assemblies is connected with the upper monitoring platform, wherein a number of sampling channels of each monitoring assembly is M; M battery cells are connected with the same monitoring assembly through a M sampling channels; a sequence of the M sampling channels is consistent with a sequence of the M battery cells; M and N are integers greater than or equal to 1; and the N monitoring assemblies are configured to acquire sampling data of M battery cells;
establishing a mapping relationship of the parameter information, communication addresses and weights of the N monitoring assemblies through a bootstrap algorithm; and
when a battery cell is abnormal, determining a location of the abnormal battery cell according to a serial number of corresponding battery cell in the monitoring assembly and the mapping relationship, and monitoring the battery cell.
